(19) United States
(12) Patent Application Publication
(10) Pub. No.: US 2010/0161257 A1
(43) Pub. Date: Jun. 24, 2010

(54) Battery wireless link

(75) Inventors: Alan Cornett, Andover, MN (US); Robert E. De Mers, Elk River, MN (US); Robert Charles Becker, Eden Prairie, MN (US)

Correspondence Address: HONEYWELL INTERNATIONAL INC.;PATENT SERVICES, 101 COLUMBIA ROAD, P O BOX 2245, MORRISTOWN, NJ, 07962-2245, US

(73) Assignee: Honeywell International Inc.

(21) Appl. No.: 12/316,931

(22) Filed: Dec. 18, 2008

(51) Int. Cl. G01R 31/36

(52) U.S. Cl. 702/63

(57) ABSTRACT

An apparatus and method for wireless communication with a battery. A sensed condition associated with the battery is provided to a microcontroller which relays this information to a wireless module for communication with a host device or remote receiver.

### BACKGROUND

The present invention pertains to a wireless communication link to a battery. More particularly, the invention pertains to circuitry operably connected to a battery for communication with a host device.

Portable devices, such as a laptop computer, use a battery pack which is typically removable and when installed, operates as a power source for the portable device. Certain features or components of such portable devices may draw or consume different levels of power, such as a motor used to spin a hard drive compared to the power consumed by a microprocessor. Thus, there is a need to know the current power remaining in the battery to determine if the battery is capable of powering all of the possible features or components of the portable device.

Voltage detection circuits have been incorporated into battery packs to check the remaining power of a battery, in terms of the voltage between the terminals of a battery. When this voltage falls below a predetermined reference value, a determination is made that the remaining charge in the battery is inadequate. This determination is then often communicated to a user display on the main device by means of a physical signal line, or electrical connection. This requires that the battery be installed in the main device in order to communicate the state of the battery to the user. Alternatively, the inadequate power determination may be communicated to a user by means of a display located on the battery pack itself.

Other conditions associated with the battery pack which may be monitored include the age of the batteries, the charging or discharging rate, temperature, current device load or current consumption, or the number of charge or discharge cycles. More than one power source may be included within a battery pack for powering multiple circuits at different times, voltages, or power levels.

### SUMMARY

The invention is a device and method for communication with a battery. A wireless link may be used to provide information concerning the battery to a host electronic device.

### BRIEF DESCRIPTION OF THE DRAWINGS

Exemplary embodiments of the invention are described below in conjunction with the appended figures, wherein like reference numerals refer to like elements in the various figures, and wherein:

FIG. 1 is a block diagram according to an exemplary embodiment; and

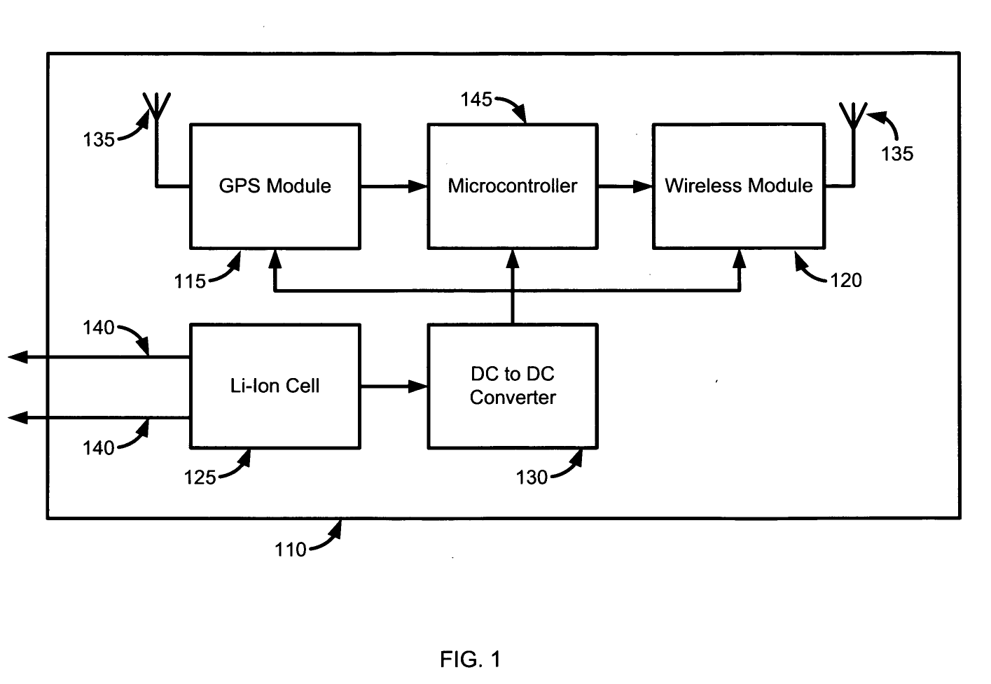

FIG. 2 is a flow diagram according to an exemplary embodiment.

### DESCRIPTION

Existing battery technology uses a direct electrical contact method of communicating battery information such as the battery charge status between a host device, such as a computer, and the battery. The present invention replaces the need for a direct electrical contact link with a wireless link.

The present invention also allows additional information to be exchanged or transmitted, such as the battery age, the number of times it has been charged, the manufacturer, the model number, and the location of the battery or host device if the battery is installed. Although the present invention describes specific data to be transmitted and example transmission protocols, one skilled in the area could easily transmit or exchange additional information or use other common wireless protocols.

This invention is an alternative means to communicating with a battery pack. It simplifies the battery physical interconnection with the device it is powering and provides a universal interface that is not specific to the physical arrangement and placement of contacts on the battery. It dispenses with the additional contacts required to communicate charge status of the battery. It also allows other communication to occur, such would occur between a security device implanted in the battery that would allow the device to be tracked in the event the computer or other device powered by the battery was stolen.

This invention implants a wireless communications device such as a Bluetooth link and additional ancillary circuitry into a battery pack for the purpose of communicating information to a host device, such as a computer. The information could include the typical information currently carried on the battery state bus, such as charge status, battery temperature, chemistry, etc. Additional information from the ancillary circuitry could include GPS position data or inertial data that would allow a stolen device to be tracked and eventually recovered. Because the space inside a battery pack is typically limited, this device would need to be very small and thin. The wireless link could be used separately from the battery state monitoring circuitry if this was desirable.

The wireless communication protocol may be selected from a number of common protocols, such as that offered by the Zigbee or Bluetooth consortiums, and would replicate the communication function without using potentially unreliable electrical contacts.

As shown, the battery pack 110 contains a voltage source 125, which may be of any common battery cell type such as Lithium Ion (Li-Ion), Nickel Cadmium (NiCd), Nickel Metal Hydride (NiMH), or others commonly used to power portable electronic devices. Not shown in the figure is any additional power management or safety electronics commonly packaged with device batteries. The voltage source 125 is connected to the host electrical device (not shown) by means of one or more electrical connectors 140. Electrical connections 140 may also be used to supply the voltage source with charging current from a charger (not shown). Voltage source 125 may also be connected to a DC-to-DC converter 130 before being connected to a microcontroller 145. The DC-to-DC converter may be used to provide the microcontroller 145 with the correct operating voltage from the voltage source 125, especially when the voltage source 125 drops to a low power level as typically happens when the cells become depleted.

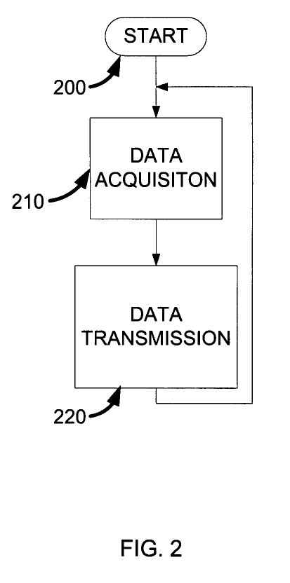

The microcontroller 145 may perform various data acquisition functions (210 of FIG. 2) such as reading the temperature within the battery pack 110 via a temperature sensing device, such as a thermistor (not shown), monitoring the voltage from the voltage source 125, or monitoring the charging current. Microcontroller 145 is also capable of accepting global-positioning data from the GPS module 115, indicating the location of the battery pack 110. The acquired or received data is then stored in RAM or other non-volatile memory (not shown) for later access and transmission.

By integrating a GPS module 115, such as a Garmin 18 OEM, or other similar inertial or dead reckoning module, into the battery pack 110, the location of the battery pack and thus the host device may be known, which may then be transmitted to a remote receiver. Typical GPS location devices are operable only when the host device has been powered on. In the present embodiment of the invention, the GPS module 115 may be intentionally or unknowingly operable even when the host device has been powered down by the user. There are many small GPS modules available in the consumer market for small handheld personal navigation devices (PND), such as the Holux M-241 wireless GPS logger, which logs location coordinates wherever the unit has traveled. Access to GPS is a significant challenge for this system. The GPS antenna will have to be placed at a location where it has at least an intermittent view of the sky in order to acquire a position fix. This will require the antenna to be placed where it is not obstructed by metal and has a reasonable view of the sky. This requires that the antenna be placed under the host device on battery packs that slip in from the bottom, or on the end of the pack behind the battery housing for those packs that slide in from the side.

The objective of the wireless (Bluetooth) module is to provide the bridge for communication or data transmission 220 to the host device. The wireless module 120 transmits the output from the microcontroller 145 to a remote monitoring device, which may be the host portable electrical device being powered by the battery pack 110. Alternatively, the remote monitoring device may be a remote receiver designed to collect information from at least one battery pack 110. A receiver used in this arrangement could simultaneously monitor specific conditions of a large number of battery packs, such as those used in a classroom.

The Bluetooth communications protocol is an ideal protocol for this type of wireless communication since it was designed for low power consumption with relatively short range. Its key features are robustness, low complexity, low power, and cost. Designed to operate in noisy frequency environments, the Bluetooth radio uses a fast acknowledgment and frequency hopping scheme to make the link more robust. Bluetooth radio modules operate in the unlicensed ISM band at 2.4 GHz, and avoid interference from other signals by hopping to a new frequency after transmitting or receiving a packet. The Parani-ESD series of Bluetooth modules offers the flexibility for wireless communication in a small form factor. Further configuration may be necessary in software or firmware design to allow the wireless module to pair and remain paired with the host device without user intervention.

The sensing and communication electronics may operate in a parasitic mode by obtaining its operating power from the host devices battery cells. This usually requires DC-DC converters to get the proper voltages for the additional hardware. A low power microcontroller or computer will act as the processing module. One example might be a Gumstix Verdex computer which provides ample processing power and storage to meet the requirements of this application. The storage may be of a non-volatile type of suitable size to store a predetermined number of sensed conditions of the battery pack.

In the present specification, some of the matter may be of a hypothetical or prophetic nature although stated in another manner or tense.

Although the invention has been described with respect to at least one illustrative example, many variations and modifications will become apparent to those skilled in the art upon reading the present specification. It is therefore the intention that the appended claims be interpreted as broadly as possible in view of the prior art to include all such variations and modifications.

1. A battery pack, comprising:
a battery for supplying power to an electronic apparatus;
a sensor proximate to the battery; and
a wireless transmission circuit for transmitting information acquired by the sensor to a remote receiver.

2. The battery pack according to claim 1, wherein said sensor is a GPS receiver.

3. The battery pack according to claim 1, wherein said sensor measures the terminal voltage of the battery.

4. The battery pack according to claim 1, wherein:
said battery pack is installed in an electronic device; and
the wireless transmission circuit operates to send information obtained from the sensor to the electronic device for further display or processing.

5. The battery pack according to claim 4 wherein the battery pack also includes a microcontroller which receives data collected by the sensor and sends it to the wireless transmission circuit for communication to the electronic device.

6. A communication method for transmitting data acquired from a battery comprising the steps of:
providing power to a microcontroller from said battery;
acquiring the data from at least one sensor capable of sensing a predetermined condition regarding said battery;
transmitting the data acquired using a wireless communication protocol to a remote receiver.

7. The communication method according to claim 6, wherein said sensor is operable to sense at least one of the following: charge status, discharge status, remaining capacity, GPS coordinates, inertial position, or temperature.

8. A battery pack, comprising:
a rechargeable battery;
a monitoring circuit coupled to said rechargeable battery for measuring a predetermined condition of said rechargeable battery;
a microcontroller coupled to said monitoring circuit capable of storing at least one value of the predetermined condition and providing an output indicative of the at least one value of the predetermined condition;
a wireless communication module capable of transmitting the output from the microcontroller to a remote receiver.

9. The battery pack of claim 8, wherein said monitoring circuit includes a GPS receiver for monitoring the location of the rechargeable battery.

10. The battery pack of claim 9, wherein said wireless communication module communicates using the Bluetooth protocol to the host device in which the rechargeable battery is being used.

11. The battery pack of claim 8 further including a non-volatile data storage device.

12. The battery pack of claim 8 wherein the battery pack is installed in a portable computer, said computer containing software which is capable of receiving the wireless transmission of the output from the microcontroller.

13. The communication method of claim 6 wherein said microcontroller includes memory, further comprising the step of storing said data in the memory for said transmission.

14. The communication method of claim 13 wherein said sensor is operable to determine the geospatial location of the battery.

15. The battery pack according to claim 2 wherein said electronic apparatus is a personal computer.

16. The battery pack according to claim 2 wherein said GPS receiver is capable of determining the geospatial location of the battery pack to allow remote tracking of the electronic apparatus and battery pack.

17. The battery pack according to claim 15 wherein said personal computer contains software which receives the wireless transmission.

18. The battery pack according to claim 17 wherein said software provides feedback on the information obtained by the sensor to the personal computer user.

19. The battery pack of claim 1 wherein said information obtained by the sensor is the remaining capacity of the battery.

20. The battery pack of claim 1 wherein said information obtained by the sensor is the charging status of said battery.
